(19) United States
(12) Patent Application Publication
(10) Pub. No.: US 2012/0040290 A1
(43) Pub. Date: Feb. 16, 2012

(54) PHOTOSENSITIVE RESIN COMPOSITION, AND PHOTOSENSITIVE ELEMENT, RESIST PATTERN FORMATION METHOD AND PRINTED CIRCUIT BOARD PRODUCTION METHOD EACH UTILIZING SAME

(75) Inventors: Yoshiki Ajioka, Ibaraki (JP); Mitsuru Ishi, Ibaraki (JP); Junichi Iso, Ibaraki (JP); Manami Usuba, Ibaraki (JP)

(73) Assignee: HITACHI CHEMICAL COMPANY, LTD., Tokyo (JP)

(21) Appl. No.: 13/256,385

(22) PCT Filed: Feb. 23, 2010
(86) PCT No.: PCT/JP2010/052746

§ 371 Date: Oct. 26, 2011

(30) Foreign Application Priority Data
Mar. 13, 2009 (JP) 2009-061210

(51) Int. Cl. G03F 7/031; H01L 21/02; G03F 7/26

(52) U.S. Cl. 430/286.1; 430/281.1; 430/319; 430/313

(57) ABSTRACT

The present invention relates to a photosensitive resin composition comprising (A) a binder polymer, (B) a photopolymerizable compound having an ethylenically unsaturated bond and (C) a photopolymerization initiator, wherein the (C) photopolymerization initiator comprises a compound represented by the following general formula (1). In formula (1), R¹ represents a halogen atom, an amino group, a carboxyl group, a C1-6 alkyl group, a C1-6 alkoxy group or a C1-6 alkylamino group and m represents an integer of 1 to 5.

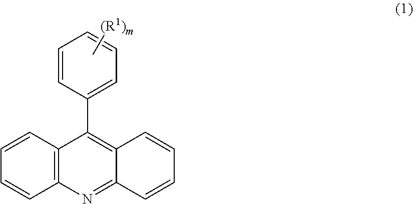

### TECHNICAL FIELD

The present invention relates to a photosensitive resin composition, and a photosensitive element, a method of a forming resist pattern and a method of producing a printed wiring board each utilizing same.

### BACKGROUND ART

In the field of producing printed wiring boards, a photosensitive resin composition and a photosensitive element obtained by laminating the composition onto a support and coating it with a protective film are conventionally widely employed as resist materials used for etching, plating and the like.

When a photosensitive element is used to produce a printed wiring board, first a photosensitive resin composition layer of the photosensitive element is laminated onto a circuit-forming board with a protective film being released, and subjected to pattern exposure through a mask film or the like, after which an unexposed portion of the photosensitive resin composition layer is removed with a developing solution to form a resist pattern. Next, the resist pattern is used as a mask for etching or plating of the circuit-forming board on which the resist pattern has been formed in order to form a circuit pattern, and finally the resist pattern of the photosensitive resin composition layer (cured portions) is released and removed from the board to obtain a printed wiring board.

In such a method of producing a printed wiring board, a laser direct drawing method in which active light rays are directly irradiated to an image pattern using digital data without a mask film, has been put to practical use. YAG lasers, semiconductor lasers and the like are used as light sources used for the laser direct drawing method for their safety, handleability and the like. In recent years, techniques using long-life and high-output gallium nitride-based blue lasers and the like as light sources have been proposed.

Moreover, in recent years, the direct drawing method referred to as a DLP (Digital Light Processing) exposure method that allows formation of finer patterns than in the conventional methods, has been adopted as a laser direct drawing method due to a need for high definitions and high densities of printed wiring boards. Generally, the DLP exposure method uses active light rays with a wavelength of 390 to 430 nm from a blue-violet semiconductor laser light source. There are mainly used exposure methods that employ polygon multi-beams with wavelength of 355 nm from a YAG laser light source, which are suitable for small-batch, multi-variety products for general purpose printed wiring boards.

In order to adapt such a laser direct drawing method, various photosensitive resin compositions have been investigated. For example, sensitizing agents suitable for each wavelength of laser light sources, having their maximum absorptions at 355 to 430 nm, have been disclosed (see Patent literatures 1 to 3, for example).

### CITATION LIST

### Patent Literature

[Patent Literature 1] JP 2005-107191 A

[Patent Literature 2] JP 2005-122123 A

[Patent Literature 3] JP 2005-215142 A

### SUMMARY OF INVENTION

### Technical Problem

The laser direct drawing method in which exposure is accomplished by high-speed movement of a laser, however, has less exposure energy per spot and lower production efficiency, compared to conventional methods involving one-shot exposure for exposure objects using a light source that effectively emits ultraviolet rays, such as a carbon arc lamp, a mercury vapor arc lamp, an ultra-high-pressure mercury lamp, a high-pressure mercury lamp and a xenon lamp. Therefore, in the laser direct drawing method, even a photosensitive resin composition comprising a sensitizing agent such as described in Patent Literatures 1 to 3 described above cannot be considered to have sufficient photosensitivity, and a photosensitive resin composition with higher photosensitivity is required.

However, increasing the amount of a photoinitiator or a sensitizing agent included in the photosensitive resin composition, for the purpose of improving photosensitivity, promotes photoreaction locally on the surface portion of the photosensitive resin composition layer and lowers the curability of the bottom portion, thus causing problems such as worsening resolution and adhesiveness of the resist pattern and resist shape that are obtained after photocuring.

Moreover, jagged edges of the resist skirt referred to as mouse bites, or floating, releasing or lacking of the resist in the resist shape can cause short-circuit or disconnection of the circuit formed by etching or plating treatment thereafter.

With such a conventional photosensitive resin composition, it has been difficult to obtain sufficient photosensitivity while well maintaining the resist shape obtained after photocuring.

The present invention has been accomplished in consideration of the problems of the prior art described above, and its object is to provide a photosensitive resin composition that is excellent in photosensitivity, resolution and adhesiveness and that can form a resist pattern with a good resist shape, as well as a photosensitive element, a method of forming a resist pattern and a method of producing a printed wiring board, each utilizing same.

### Solution to Problem

The present invention provides a photosensitive resin composition comprising (A) a binder polymer, (B) a photopolymerizable compound having an ethylenically unsaturated bond and (C) a photopolymerization initiator, wherein the (C) photopolymerization initiator comprises a compound represented by the following general formula (1).

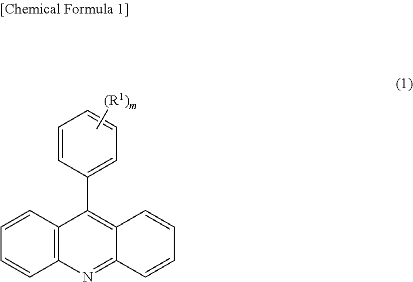

[In formula (1), R¹ represents a halogen atom, an amino group, a carboxyl group, a C1-6 alkyl group, a C1-6 alkoxy group or a C1-6 alkylamino group, and m represents an integer of 1 to 5. When m is 2 or greater, the multiple R¹ groups may be the same or different.]

The photosensitive resin composition of the present invention has the structure described above and therefore is excellent in photosensitivity, resolution and adhesiveness and can form a resist pattern with good resist shape.

The (C) photopolymerization initiator in the photosensitive resin composition of the present invention may further comprise a compound represented by the following general formula (2). This can further improve the photosensitivity and the resolution of the photosensitive resin composition.

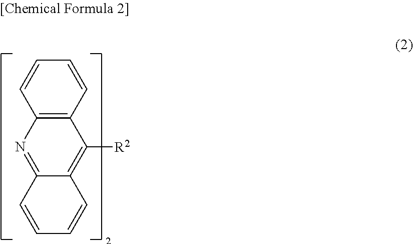

[In formula (2), R² represents a C2-20 alkylene group, a C2-20 oxadialkylene group or a C2-20 thiodialkylene group.]

The photosensitive resin composition of the present invention may further comprise (D) a compound represented by the following general formula (3). This can still further improve the photosensitivity and the resist shape of the photosensitive resin composition.

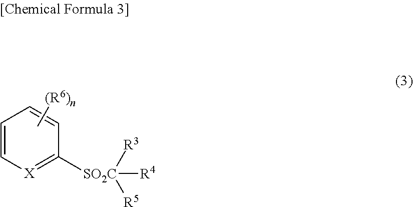

[In formula (3), X represents a carbon or nitrogen atom, R³, R⁴ and R⁵ each independently represent a halogen atom or a C1-5 alkyl group and at least one of R³, R⁴ and R⁵ is a halogen atom, R⁶ represents a C1-5 alkyl group or a C1-5 alkyl alkoxy group and n represents an integer of 0 to 4. When n is 2 or greater, the multiple R⁶ groups may be the same or different.]

When the (A) binder polymer in the photosensitive resin composition of the present invention has a structural unit based on a (meth)acrylic acid, the developability and release property can be further improved. Moreover, when the (A) binder polymer has a structural unit based on styrene or a styrene derivative, the photosensitivity, resolution and adhesiveness can be further improved.

The (B) photopolymerizable compound having an ethylenically unsaturated bond in the photosensitive resin composition of the present invention preferably comprises a bisphenol A-based (meth)acrylate compound. This can further improve the photosensitivity, resolution and adhesiveness of the photosensitive resin composition.

Furthermore, when the (B) photopolymerizable compound having an ethylenically unsaturated bond comprises a compound represented by the following general formula (4), the photosensitivity and release property of the photosensitive resin composition can be further improved.

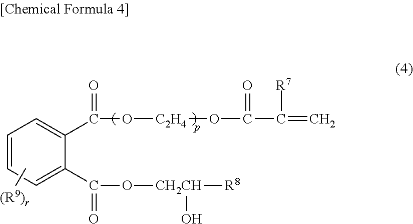

[In formula (4), R⁷ represents a hydrogen atom or a methyl group, R⁸ represents a hydrogen atom, a methyl group or a halogenated methyl group, R⁹ represents a C1-5 alkyl group, a halogen atom or a hydroxyl group, p represents an integer of 1 to 4 and r represents an integer of 0 to 4. When r is 2 or greater, the multiple R⁹ groups may be the same or different.]

The present invention also provides a photosensitive element comprising a support and a photosensitive resin composition layer comprising the photosensitive resin composition described above, formed on the support. The photosensitive element of the present invention is provided with the photosensitive resin composition layer comprising the photosensitive resin composition described above, and therefore can form a resist pattern which is all excellent in the resolution, adhesiveness and resist shape with high sensitivity and efficiency.

The present invention also provides a method of forming a resist pattern that comprises a lamination step of laminating a photosensitive resin composition layer comprising the photosensitive resin composition described above or a photosensitive resin composition layer of the photosensitive element described above on a circuit-forming board, an exposure step irradiating a prescribed portion of the photosensitive resin composition layer with active light rays to photocure the exposed portion, and a developing step of removing a portion other than the exposed portion of the photosensitive resin composition layer to form a resist pattern. This allows formation of a resist pattern which is all excellent in the resolution, adhesiveness, and resist shape, with high sensitivity and efficiency.

The exposure step described above in the method of forming a resist pattern of the present invention is preferably a step of subjecting the photosensitive resin composition layer to direct drawing exposure with a laser light to photocure the exposed portion.

This method of forming a resist pattern can more efficiently form a resist pattern with a good resist shape, because exposure by a laser direct drawing method is carried out using the photosensitive resin composition or photosensitive element described above.

The present invention also provides a method of producing a printed wiring board which comprises a step of etching or plating the circuit-forming board on which a resist pattern has been formed by the resist pattern formation method. This allows efficient production of a printed wiring board and realization of high-density wiring.

### Advantageous Effects of Invention

According to the present invention, it is possible to provide a photosensitive resin composition that is excellent in photosensitivity, resolution and adhesiveness and that is able to form a resist pattern with good resist shape, as well as a photosensitive element, a method of forming a resist pattern and a method of producing a printed wiring board, each utilizing same.

### BRIEF DESCRIPTION OF DRAWINGS

FIG. 1 is a schematic cross-sectional view showing a preferred embodiment of a photosensitive element of the present invention.

### DESCRIPTION OF EMBODIMENTS

The present invention will be explained in detail below. The term “(meth)acrylic acid” as used herein means acrylic acid or a corresponding methacrylic acid therewith, “(meth)acrylate” means acrylate or a corresponding methacrylate therewith, and “(meth)acryloyl group” means acryloyl or a corresponding methacryloyl group therewith.

[Photosensitive Resin Composition]

The photosensitive resin composition of the present invention comprises (A) a binder polymer (hereinbelow also referred to as “component (A)”), (B) a photopolymerizable compound having an ethylenically unsaturated bond (hereinbelow also referred to as “component (B)”) and (C) a photopolymerization initiator (hereinbelow also referred to as “component (C)”).

Component (A): Binder Polymer

Any binder polymers can be used as the (A) binder polymer without particular restrictions, provided that they can provide a film-forming property. Examples of the (A) binder polymer include acrylic resins, styrene resins, epoxy resins, amide resins, amide/epoxy resins, alkyd resins and phenol resins. From the viewpoint of the alkali developability, acrylic resins are preferred. These may be used alone or in combinations of two or more.

The (A) binder polymer may be produced, for example, by radical polymerization of a polymerizable monomer. Examples of polymerizable monomers described above include styrene, polymerizable styrene derivatives substituted at the α-position or on the aromatic ring such as vinyltoluene, α-methylstyrene and p-methylstyrene; acrylamides such as diacetoneacrylamide; vinyl alcohol esters such as vinyl-n-butyl ether; acrylic acid derivatives such as alkyl(meth)acrylate ester, benzyl(meth)acrylate ester, tetrahydrofurfuryl(meth)acrylate ester, dimethylaminoethyl(meth)acrylate ester, diethylaminoethyl(meth)acrylate ester, glycidyl(meth)acrylate ester, 2,2,2-trifluoroethyl(meth)acrylate, 2,2,3,3-tetrafluoropropyl(meth)acrylate, (meth)acrylic acid, α-bromo(meth)acrylic acid, α-chlor(meth)acrylic acid, β-furyl(meth)acrylic acid and β-styryl(meth)acrylic acid; maleic acid, maleic acid derivatives such as maleic anhydride, monomethyl maleate, monoethyl maleate and monoisopropyl maleate; derivatives of organic acids such as fumaric acid, cinnamic acid, α-cyanocinnamic acid, itaconic acid, crotonic acid and propiolic acid; and acrylonitrile. These may be used alone or in combinations of two or more.

Examples of the alkyl(meth)acrylate esters described above include compounds represented by the following general formula (5), and the same compounds with the alkyl group substituted with a hydroxyl group, an epoxy group, a halogen group or the like.

H₂C═C(R¹⁰)—COOR¹¹ (5)

In formula (5), R¹⁰ represents a hydrogen atom or a methyl group, R¹¹ represents a C1-12 alkyl group, R¹¹ is preferably a C1-8 alkyl group and more preferably a C1-4 alkyl group. Examples of C1-12 alkyl groups represented by R¹¹ in formula (5) include a methyl group, an ethyl group, a propyl group, a butyl group, a pentyl group, a hexyl group, a heptyl group, an octyl group, a nonyl group, a decyl group, an undecyl group and a dodecyl group and structural isomers thereof.

Examples of the monomer represented by general formula (5) described above include methyl(meth)acrylate ester, ethyl(meth)acrylate ester, propyl(meth)acrylate ester, butyl(meth)acrylate ester, pentyl(meth)acrylate ester, hexyl(meth)acrylate ester, heptyl(meth)acrylate ester, octyl(meth)acrylate ester, 2-ethylhexyl(meth)acrylate ester, nonyl(meth)acrylate ester, decyl(meth)acrylate ester, undecyl(meth)acrylate ester and dodecyl(meth)acrylate ester. These may be used alone or in combinations of two or more.

The (A) binder polymer preferably comprises a carboxyl group from the viewpoint of the alkali developability. The binder polymer having a carboxyl group may be produced, for example, by radical polymerization of a carboxyl group-containing polymerizable monomer and another polymerizable monomer. (Meth)acrylic acid is preferred as the carboxyl group-containing polymerizable monomer described above, and methacrylic acid is especially preferred.

The carboxyl group content of the (A) binder polymer (the proportion of polymerizable monomers with a carboxyl group to total polymerizable monomers used) is preferably 12 to 50 wt %, based on the total mass of the component (A), from the viewpoint of a balance between alkali developability and alkali resistance. The carboxyl group content of the (A) binder polymer is preferably 12 wt % or more and more preferably 15 wt % or more, in terms of good alkali developability. The carboxyl group content of the (A) binder polymer is preferably 50 wt % or less, more preferably 40 wt % or less, even more preferably 30 wt % or less and most preferably 25 wt % or less, in terms of developing solution resistance.

From the viewpoint of adhesiveness and release property, the (A) binder polymer preferably also contains styrene or a styrene derivative as a polymerizable monomer.

When styrene or a styrene derivative is used as the copolymerizing component in the component (A), the content (the proportion of the styrene or styrene derivative to the total polymerizable monomer used) is preferably 0.1 to 40 wt %, based on the total mass of the component (A), from the viewpoint of achieving good adhesiveness and release property. Moreover, in terms of good adhesiveness, the content is preferably 0.1 wt % or more, more preferably 1 wt % or more and even more preferably 1.5 wt % or more, and in terms of good release property, it is preferably 30 wt % or less, preferably 28 wt % or less and even more preferably 27 wt % or less.

Such binder polymers are used alone or in combinations of two or more. Examples of binder polymers, when two or more are used in combination, include two or more binder polymers composed of different copolymerizing components, two or more binder polymers with different weight-average molecular weights, and two or more binder polymers with different degrees of dispersion.

From the viewpoint of a balance between mechanical strength and alkali developability, the weight-average molecular weight (hereinbelow represented as “Mw”) of the (A) binder polymer is preferably 20,000 to 300,000. In terms of providing good film property and developing solution resistance, the Mw of the (A) binder polymer is preferably 20,000 or more, more preferably 40,000 and even more preferably 50,000. In terms of good alkali developability, the Mw of the (A) binder polymer is preferably 300,000 or less, more preferably 150,000 or less and even more preferably 120,000 or less. The weight-average molecular weight in the present invention is the value obtained by measurement by gel permeation chromatography and calculation using a calibration curve prepared using standard polystyrene.

From the viewpoint of achieving better coating film property of the photosensitive resin composition and strength of photocured article, the content of the component (A) is preferably 30 to 80 parts by weight, more preferably 40 to 75 parts by weight and even more preferably 50 to 70 parts by weight, with respect to 100 parts by weight as the total amount (solid content) of component (A) and component (B).

Component (B): Photopolymerizable Compound Having an Ethylenically Unsaturated Bond

The (B) photopolymerizable compound having an ethylenically unsaturated bond is not particularly restricted, provided that it has at least one ethylenically unsaturated bond. Examples of the (B) photopolymerizable compound include compounds obtained by reacting a polyhydric alcohol with an α,β-unsaturated carboxylic acid, bisphenol A-based (meth)acrylate compounds, compounds obtained by reacting a glycidyl group-containing compound with an α,β-unsaturated carboxylic acid, urethane monomers such as urethane bond-containing (meth)acrylate compounds, γ-chloro-β-hydroxypropyl-β′-(meth)acryloyloxyethyl-o-phthalate, β-hydroxyethyl-β′-(meth)acryloyloxyethyl-o-phthalate, β-hydroxypropyl-β′-(meth)acryloyloxyethyl-o-phthalate, alkyl(meth)acrylate esters and compounds represented by the following general formula (4). These are used alone or in combinations of two or more.

Among them, from the viewpoint of achieving good photosensitivity and release property, it is preferable to contain a compound represented by the following general formula (4), and from the view point of achieving good photosensitivity, resolution and adhesiveness, it is preferable to contain a bisphenol A-based (meth)acrylate compound.

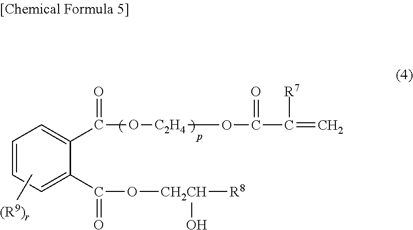

In formula (4), R⁷ represents a hydrogen atom or a methyl group. R⁸ represents a hydrogen atom, a methyl group or a halogenated methyl group, and it is preferably a hydrogen atom or a halogenated methyl group. Examples of a halogen atom of the halogenated methyl group include Cl, Br and F, but from the viewpoint of obtaining effects of the present invention more certainly, the halogen atom is preferably Cl. R⁹ represents a C1-5 alkyl group, a halogen atom or a hydroxyl group, and it is preferably a C1-5 alkyl group or a halogen atom. p represents an integer of 1 to 4 and it is preferably an integer of 1 to 2, and r represents an integer of 0 to 4 and it is preferably an integer of 0 to 2. When r is 2 or greater, the multiple R⁹ groups may be the same or different.

Examples of the compound represented by the general formula (4) include γ-chloro-β-hydroxypropyl-β′-(meth)acryloyloxyethyl-o-phthalate, β-hydroxyethyl-β′-(meth)acryloyloxyethyl-o-phthalate, β-hydroxypropyl-β′-(meth)acryloyloxyethyl-o-phthalate and the like, and among them, γ-chloro-β-hydroxypropyl-β′-(meth)acryloyloxyethyl-o-phthalate is preferable. γ-chloro-β-hydroxypropyl-β′-(meth)acryloyloxyethyl-o-phthalate is commercially available as FA-MECH (product name of Hitachi Chemical Co., Ltd.). These may be used alone or in combinations of two or more.

When the component (B) comprises a compound represented by the general formula (4), from the viewpoint of a balance between photosensitivity, release property and coating film property, the content of the compound is preferably 1 to 50 wt %, more preferably 5 to 45 wt % and even more preferably 10 to 40 wt %, based on the total mass of the component (B).

Examples of the bisphenol A-based (meth)acrylate compound include 2,2-bis(4-((meth)acryloxypolyethoxy)phenyl)propanes, 2,2-bis(4-((meth(acryloxypolypropoxy)phenyl)propanes and 2,2-bis(4-((meth(acryloxypolyethoxypolypropoxy)phenyl)propanes. From the viewpoint of further improving resolution, 2,2-bis(4-((meth)acryloxypolyethoxy)phenyl)propanes are preferable among them.

Examples of the 2,2-bis(4-((meth)acryloxypolyethoxy)phenyl)propanes include 2,2-bis(4-((meth)acryloxydiethoxy)phenyl)propane, 2,2-bis(4-((meth)acryloxytriethoxy)phenyl)propane, 2,2-bis(4-((meth)acryloxytetraethoxy)phenyl)propane, 2,2-bis(4-((meth)acryloxypentaethoxy)phenyl)propane, 2,2-bis(4-((meth)acryloxyhexaethoxy)phenyl)propane, 2,2-bis(4-((meth)acryloxyheptaethoxy)phenyl)propane, 2,2-bis(4-((meth)acryloxyoctaethoxy)phenyl)propane, 2,2-bis(4-((meth)acryloxynonaethoxy)phenyl)propane, 2,2-bis(4-((meth)acryloxydecaethoxy)phenyl)propane, 2,2-bis(4-((meth)acryloxyundecaethoxy)phenyl)propane, 2,2-bis(4-((meth)acryloxydodecaethoxy)phenyl)propane, 2,2-bis(4-((meth)acryloxytridecaethoxy)phenyl)propane, 2,2-bis(4-((meth)acryloxytetradecaethoxy)phenyl)propane, 2,2-bis(4-((meth)acryloxypentadecaethoxy)phenyl)propane and 2,2-bis(4-((meth)acryloxyhexadecaethoxy)phenyl)propane. 2,2-bis(4-(methacryloxypentaethoxy)phenyl)propane is commercially available as BPE-500 (product name of Shin-Nakamura Chemical Co., Ltd.) and 2,2-bis(4-(methacryloxypentadecaethoxy)phenyl)propane is commercially available as BPE-1300 (product name of Shin-Nakamura Chemical Co., Ltd.). These may be used alone or in combinations of two or more.

Examples of the 2,2-bis(4-((meth(acryloxypolypropoxy)phenyl)propanes include 2,2-bis(4-((meth)acryloxydipropoxy)phenyl)propane, 2,2-bis(4-((meth)acryloxytripropoxy)phenyl)propane, 2,2-bis(4-((meth)acryloxytetrapropoxy)phenyl)propane, 2,2-bis(4-((meth)acryloxypentapropoxy)phenyl)propane, 2,2-bis(4-((meth)acryloxyhexapropoxy)phenyl)propane, 2,2-bis(4-((meth)acryloxyheptapropoxy)phenyl)propane, 2,2-bis(4-((meth)acryloxyoctapropoxy)phenyl)propane, 2,2-bis(4-((meth)acryloxynonapropoxy)phenyl)propane, 2,2-bis(4-((meth)acryloxydecapropoxy)phenyl)propane, 2,2-bis(4-((meth)acryloxyundecapropoxy)phenyl)propane, 2,2-bis(4-((meth)acryloxydodecapropoxy)phenyl)propane, 2,2-bis(4-((meth)acryloxytridecapropoxy)phenyl)propane, 2,2-bis(4-((meth)acryloxytetradecapropoxy)phenyl)propane, 2,2-bis(4-((meth)acryloxypentadecapropoxy)phenyl)propane and 2,2-bis(4-((meth)acryloxyhexadecapropoxy)phenyl)propane. These may be used alone or in combinations of two or more.

Examples of the 2,2-bis(4-((meth(acryloxypolyethoxypolypropoxy)phenyl)propanes include 2,2-bis(4-((meth)acryloxydiethoxyoctapropoxy)phenyl)propane, 2,2-bis(4-((meth)acryloxytetraethoxytetrapropoxy)phenyl)propane and 2,2-bis(4-((meth)acryloxyhexaethoxyhexapropoxy)phenyl)propane. These may be used alone or in combinations of two or more.

When the component (B) comprises a bisphenol A-based (meth)acrylate compound, from the viewpoint of a balance between photosensitivity and resolution, the content of the compound is preferably 10 to 90 wt % and more preferably 20 to 85 wt %, based on the total mass of the component (B).

Examples of the compounds obtained by reacting a polyhydric alcohol with an α,β-unsaturated carboxylic acid include polyethyleneglycol di(meth)acrylates having 2 to 14 ethylene groups, polypropyleneglycol di(meth)acrylates having 2 to 14 propylene groups, polyethylenepolypropyleneglycol di(meth)acrylates having 2 to 14 ethylene groups and 2 to 14 propylene groups, trimethylolpropane di(meth)acrylate, trimethylolpropane tri(meth)acrylate, trimethylolpropaneethoxy tri(meth)acrylate, trimethylolpropanediethoxy tri(meth)acrylate, trimethylolpropanetriethoxy tri(meth)acrylate, trimethylolpropanetetraethoxy tri(meth)acrylate, trimethylolpropanepentaethoxy tri(meth)acrylate, tetramethylolmethane tri(meth)acrylate, tetramethylolmethane tetra(meth)acrylate, polypropyleneglycol di(meth)acrylate having 2 to 14 propylene groups, dipentaerythritol penta(meth)acrylate and dipentaerythritol hexa(meth)acrylate. These may be used alone or in combinations of two or more.

Examples of the urethane monomers described above include addition reaction products of a (meth)acrylic monomer having a hydroxyl group at the (3 position and a diisocyanate compound such as isophorone diisocyanate, 2,6-toluene diisocyanate, 2,4-toluene diisocyanate and 1,6-hexamethylene diisocyanate, as well as tris((meth)acryloxytetraethyleneglycol isocyanate)hexamethylene isocyanurate, EO-modified urethane di(meth)acrylate and EO,PO-modified urethane di(meth)acrylate. “EO” indicates ethylene oxide, and an EO-modified compound has a block structure of an ethylene oxide group. “PO” indicates propylene oxide, and a PO-modified compound has a block structure of a propylene oxide group. Examples of the EO-modified urethane di(meth)acrylate include “UA-11”, product name of Shin-Nakamura Chemical Co., Ltd. Examples of the EO,PO-modified urethane di(meth)acrylate include “UA-13”, product name of Shin-Nakamura Chemical Co., Ltd. Examples of tris((meth)acryloxytetraethyleneglycol isocyanate)hexamethylene isocyanurate include “UA-21”, product name of Shin-Nakamura Chemical Co., Ltd. These urethane monomers may be used alone or in combinations of two or more.

When the component (B) comprises an urethane monomer, from the viewpoint of further improving tent tear rate, the content of the urethane monomer is preferably 5 to 40 wt % and more preferably 10 to 35 wt %, based on the total mass of the component (B).

The component (B) content is preferably 20 to 70 parts by weight, more preferably 25 to 60 parts by weight and even more preferably 30 to 50 parts by weight, with respect to 100 parts by weight as the total amount (solid content) of component (A) and component (B). When the content of the component (B) is in this range, photosensitivity and coating film property of the photosensitive resin composition become better.

Component (C): Photopolymerization Initiator

The (C) photopolymerization initiator comprises a compound represented by the following general formula (1).

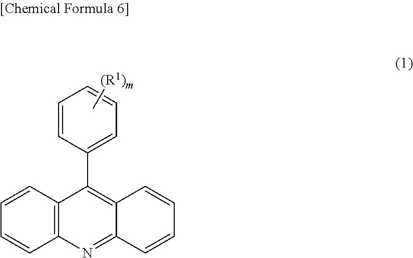

In formula (1), R¹ represents a halogen atom, an amino group, a carboxyl group, a C1-6 alkyl group, a C1-6 alkoxy group or a C1-6 alkylamino group. From the viewpoint of obtaining the effects of the present invention more certainly, R¹ is preferably a halogen atom, a C1-6 alkyl group or a C1-6 alkoxy group, more preferably a halogen atom or a C1-6 alkyl group, even more preferably a C1-6 alkyl group and most preferably a C1-3 alkyl group. m represents an integer of 1 to 5, and from the viewpoint of obtaining the effects of the present invention more certainly, it is preferably an integer of 1 to 3 and preferably an integer of 1 to 2. When m is 2 or greater, the multiple R¹ groups may be the same or different.

Examples of the compound represented by general formula (1) described above include 9-(p-methylphenyl)acridine, 9-(p-ethylphenyl)acridine, 9-(p-n-propylphenyl)acridine, 9-(p-iso-propylphenyl)acridine, 9-(p-n-butylphenyl)acridine, 9-(p-tert-butylphenyl)acridine, 9-(p-methoxyphenyl)acridine, 9-(p-ethoxyphenyl)acridine, 9-(p-propoxyphenyl)acridine, 9-(p-aminophenyl)acridine, 9-(p-dimethylaminophenyl)acridine, 9-(p-diethylaminophenyl)acridine, 9-(p-chlorophenyl)acridine, 9-(p-bromophenyl)acridine, 9-(m-methylphenyl)acridine, 9-(m-n-propylphenyl)acridine, 9-(m-iso-propylphenyl)acridine, 9-(m-n-butylphenyl)acridine, 9-(m-tert-butylphenyl)acridine, 9-(m-methoxyphenyl)acridine, 9-(m-ethoxyphenyl)acridine, 9-(m-propoxyphenyl)acridine, 9-(m-aminophenyl)acridine, 9-(m-dimethylaminophenyl)acridine, 9-(m-diethylaminophenyl)acridine, 9-(m-chlorophenyl)acridine and 9-(m-bromophenyl)acridine. These may be used alone or in combinations of two or more.

The content of the compound represented by general formula (1) in the photosensitive resin composition of the present invention is preferably 0.01 to 10 parts by weight, with respect to 100 parts by weight as the total amount (solid content) of component (A) and component (B). In terms of good photosensitivity and adhesiveness, the content of the compound represented by general formula (1) is preferably 0.01 parts by weight or more, more preferably 0.05 parts by weight or more and even more preferably 0.1 parts by weight or more. In terms of achieving good resist shape, the content of the compound represented by general formula (1) is preferably 10 parts by weight or less, more preferably 5 parts by weight or less, even more preferably 3 parts by weight or less and most preferably 1 parts by weight or less.

Moreover, the component (C) may comprise a compound represented by the following general formula (2), from the viewpoint of further improving photosensitivity and resolution.

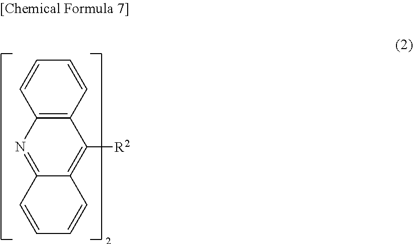

In formula (2), R² represents a C2-20 alkylene group, a C2-20 oxadialkylene group or a C2-20 thiodialkylene group. From the viewpoint of obtaining the effects of the present invention more certainly, R² is preferably a C2-20 alkylene group and more preferably a C4-14 alkylene group.

Examples of the compound represented by general formula (2) include bis(9-acridinyl)alkanes such as 1,2-bis(9-acridinyl)ethane, 1,3-bis(9-acridinyl)propane, 1,4-bis(9-acridinyl)butane, 1,5-bis(9-acridinyl)pentane, 1,6-bis(9-acridinyl)hexane, 1,7-bis(9-acridinyl)heptane, 1,8-bis(9-acridinyl)octane, 1,9-bis(9-acridinyl)nonane, 1,10-bis(9-acridinyl)decane, 1,11-bis(9-acridinyl)undecane, 1,12-bis(9-acridinyl)dodecane, 1,14-bis(9-acridinyl)tetradecane, 1,16-bis(9-acridinyl)hexadecane, 1,18-bis(9-acridinyl)octadecane, and 1,20-bis(9-acridinyl)eicosane, 1,3-bis(9-acridinyl)-2-oxapropane, 1,3-bis(9-acridinyl)-2-thiapropane and 1,5-bis(9-acridinyl)-3-thiapentane. These may be used alone or in combinations of two or more.

The (C) photopolymerization initiator preferably comprises the compound represented by general formula (2) described above wherein R² is a heptylene group (for example, “N-1717”, product name of ADEKA Co., Ltd.).

When the (C) photopolymerization initiator comprises a compound represented by general formula (2), from the viewpoint of a balance between photosensitivity, resolution and adhesiveness, and resist shape, the content of the compound is preferably 0.01 to 10 parts by weight, more preferably 0.05 to 5 parts by weight, even more preferably 0.1 to 3 parts by weight and most preferably 0.5 to 1.5 parts by weight, with respect to 100 parts by weight as the total amount (solid content) of component (A) and component (B).

The component (C) may comprise a photopolymerization initiator other than the compound represented by general formula (1) or (2). Examples of the photopolymerization initiator other than the compound represented by general formula (1) or (2) include acridines such as 9-phenylacridine and 9-alkylaminoacridine, aromatic ketones such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butanone-1 and 2-methyl-1-[4-(methylthio)phenyl]-2-morpholino-propanone-1, quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone and 2,3-dimethylanthraquinone, benzoinether compounds such as benzoinmethyl ether, benzoinethyl ether and benzoinphenyl ether, benzoin compounds such as benzoin, methylbenzoin and ethylbenzoin, benzyl derivatives such as benzyldimethylketal, substituted anthracenes such as 9,10-dimethoxyanthracene, 9,10-diethoxyanthracene, 9,10-dipropoxyanthracene, 9,10-dibutoxyanthracene and 9,10-dipentoxyanthracene, 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer and 2-(p-methoxyphenyl)-4,5-diphenylimidazole dimer, coumarin-based compounds, oxazole-based compounds, pyrazoline-based compounds and triarylamine-based compounds. Two aryl substituents in 2,4,5-triarylimidazoles may be identical for a symmetrical compound, or they may be different for an asymmetrical compound. A combination of thioxanthone-based compound and tertiary amine compound may also be used, such as a combination of diethylthioxanthone and dimethylaminobenzoic acid. They may be used alone or in combinations of two or more.

The content of the component (C) is preferably 0.01 to 20 parts by weight, more preferably 0.1 to 10 parts by weight and even more preferably 0.2 to 5 parts by weight, with respect to 100 parts by weight as the total amount (solid content) of component (A) and component (B).

If the content of the component (C) is within this range, the photosensitivity and internal photocuring property of the photosensitive resin composition will be better.

Component (D): Compound Represented by the Following General Formula (3)

The photosensitive resin composition of the present invention may further comprise a (D) compound represented by general formula (3), from the viewpoint of photosensitivity and resist shape.

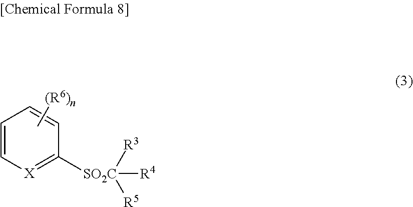

In formula (3), X represents a carbon atom or a nitrogen atom, and from the viewpoint of obtaining the effects of the present invention more certainly, it is preferably a carbon atom. R³, R⁴ and R⁵ each independently represent a halogen atom or a C1-5 alkyl group, at least one of R³, R⁴ and R⁵ represents a halogen atom and at least two of R³, R⁴ and R⁵ preferably represent a halogen atom. Examples of the halogen atom include Cl, Br and F, but from the viewpoint of achieving better photosensitivity, the halogen atom is preferably Br. The C1-5 alkyl group may be linear or branched, and examples of the C1-5 alkyl group include a methyl group, an ethyl group, a propyl group, a butyl group and a pentyl group and structural isomers thereof. Such alkyl groups may have any substituents as long as they do not inhibit the effects of the present invention. R⁶ represents a C1-5 alkyl group or a C1-5 alkoxy group, and n represents an integer of 0 to 4. When n is 2 or greater, the multiple R⁶ groups may be the same or different.

Examples of the compound represented by general formula (3) include tribromomethylphenyl sulfone and 2-tribromomethylsulfonylpyridine. These may be used alone or in combinations of two or more. For example, BMPS (product name of Sumitomo Seika Chemicals Co., Ltd.) and the like are commercially available as these compounds.

When the photosensitive resin composition of the present invention comprises a (D) compound represented by general formula (3), the content of the compound is preferably 0.01-10 parts by weight, with respect to 100 parts by weight as the total amount (solid content) of component (A) and component (B). In terms of good photosensitivity, the content of the component (D) is preferably 0.01 parts by weight or more, more preferably 0.05 parts by weight or more, even more preferably 0.2 parts by weight or more, and in terms of no film coloring, it is preferably 10 parts by weight or less.

Other Components

The photosensitive resin composition of the present invention may contain, if necessary, each about 0.01 to 20 parts by weight of a dye such as Malachite Green, Victoria Pure Blue, Brilliant Green or Methyl Violet, a photochromic agent such as leuco crystal violet, diphenylamine, benzylamine, triphenylamine, diethylaniline or o-chloroaniline, a thermal development inhibitor, a plasticizer such as p-toluenesulfonamide, a pigment, a filler, an antifoaming agent, a flame retardant, a tackifier, a leveling agent, a release promoter, an antioxidant, a polymerization inhibitor, an aromatic, an imaging agent, a thermal crosslinking agent or the like, with respect to 100 parts by weight as the total amount (solid content) of component (A) and component (B). These may be used alone or in combinations of two or more.

The photosensitive resin composition of the present invention may, if necessary, be dissolved in a solvent such as methanol, ethanol, acetone, methyl ethyl ketone, methylcellosolve, ethylcellosolve, toluene, N,N-dimethylformamide or propyleneglycol monomethyl ether, or a mixed solvent thereof, to be coated as a solution with a solid content of about 30 to 60 wt %. These may be used alone or in combinations of two or more.

Without any particular restrictions, the photosensitive resin composition of the present invention is preferably coated as a liquid resist onto the surface of a metal such as copper, a copper-based alloy, nickel, chromium, iron or an iron-based alloy such as stainless steel, and preferably copper, a copper-based alloy or an iron-based alloy, and then dried and subsequently covered with a protective film if necessary, or else used in the form of a photosensitive element.

[Photosensitive Element]

The photosensitive element of the present invention is provided with a support and a photosensitive resin composition layer formed onto the support, and a protective film may be further provided on and covering the photosensitive resin composition layer.

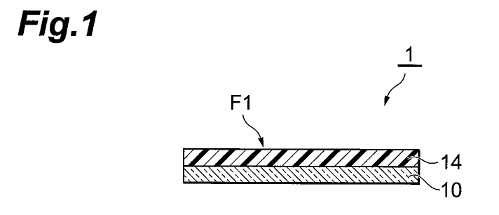

FIG. 1 is a schematic cross-sectional view showing a preferred embodiment of a photosensitive element of the present invention. The photosensitive element 1 shown in FIG. 1 has a structure with a photosensitive resin composition layer 14 laminated on a support 10. The photosensitive resin composition layer 14 is a layer composed of a photosensitive resin composition of the present invention as described above. The side F1 of the photosensitive resin composition layer 14 opposite the support side in the photosensitive element 1 may also be covered with a protective film (not shown), if necessary.

The support 10 described above is, for example, a polymer film having heat resistance and solvent resistance, such as polypropylene, polyethylene or polyesters such as polyethylene terephthalate. From the viewpoint of transparency, a polyethylene terephthalate film is preferably used.

Moreover, since such polymer films must be subsequently removable from the photosensitive resin composition layer, they must not be made of a material or surface-treated in a manner that would prevent their removal. The thickness of such polymer films is preferably 1 to 100 μm, more preferably 1 to 50 μm and even more preferably 1 to 30 μm. If the thickness is less than 1 μm, the support film will tend to tear when releasing the support film. In terms of good resolution, the thickness is preferably 100 μm or less, more preferably 50 μm or less and even more preferably 30 μm or less.

Such polymer films may be laminated on both sides of the photosensitive resin composition layer, with one of the films as a support for the photosensitive resin composition layer, another of the films as a protective film for the photosensitive resin composition.

The protective film described above is preferably one such that the adhesive force between the photosensitive resin composition layer and the protective film is lower than the adhesive force between the photosensitive resin composition layer and the support, and it is also preferably a low-fisheye film.

The photosensitive composition is coated onto the support 10 and dried to form the photosensitive resin composition layer 14.

The coating may be accomplished by a known method such as roll coating, comma coating, gravure coating, air knife coating, die coating, bar coating or spray coating. The drying may be carried out at 70 to 150° C. for about 5 to 30 minutes. The amount of residual organic solvent in the photosensitive resin composition layer is preferably 2 wt % or less, from the viewpoint of preventing diffusion of the organic solvent in subsequent steps.

The thickness of the photosensitive resin composition layer will differ depending on the use, but the post-drying thickness is preferably 1 to 200 μm, more preferably 5 to 100 μm and even more preferably 10 to 50 μm. A thickness of less than 1 μm will tend to hamper industrial coating, while a thickness of greater than 200 μm will have lower the effects of the present invention and tend to result in lower sensitivity, thus impairing the photocuring property at the base of the resist.

The photosensitive element may also comprise an interlayer such as a cushion layer, an adhesive layer, a photoabsorbing layer or gas barrier layer. The photosensitive element obtained in this manner is stored, for example, in a sheet form or in a roll form by winding it around a core. An edge separator is preferably installed at the edge of the roll form photosensitive element roll from the viewpoint of edge protection, while from the viewpoint of preventing edge fusion, a moisture-proof edge separator is preferably installed. Examples of the core include, for example, a plastic such as polyethylene resin, polypropylene resin, polystyrene resin, polyvinyl chloride resin or ABS (acrylonitrile-butadiene-styrene copolymer).

[Method of Forming a Resist Pattern]

The method of forming a resist pattern according to this embodiment will now be explained. The method of forming a resist pattern according to this embodiment is a method comprising a lamination step of laminating the photosensitive resin composition layer consisting the photosensitive resin composition according to the above embodiment, or the photosensitive resin composition layer of the photosensitive element on a board, an exposure step of irradiating a prescribed portion of the photosensitive resin composition layer with active light rays to photocure the exposed portion, and a developing step of removing a portion other than the exposed portion to form a resist pattern.

One method of forming a resist pattern of this embodiment is one which involves laminating a photosensitive resin composition layer comprising the photosensitive resin composition described above on a board (circuit-forming board), irradiating it with active light rays in an image pattern to photocure the exposed portion, and removing an unexposed portion (photocured portion) by development.

The board used here is not particularly restricted, but usually, a circuit-forming board comprising an insulating layer and a conductive layer formed on the insulating layer is used.

Lamination of the photosensitive resin composition layer on the board may be accomplished by coating the photosensitive resin composition on the board by a method such as a screen printing, spraying, roll coating, curtain coating or electrostatic coating, and drying the coating film at 60 to 110° C.

Another resist pattern formation method of this embodiment is one which involves laminating the photosensitive element 1 onto a board so as to bond the photosensitive resin composition layer 14, irradiating it with active light rays in an image pattern to photocure the exposed portion, and removing an unexposed portion (photocured portion) by development.

When the protective film described above is presence during formation of a resist pattern using a photosensitive element, the method may involve removing the protective film and then contact bonding the photosensitive resin composition layer to the circuit-forming board while heating it for lamination, and the lamination is preferably carried out under reduced pressure from the viewpoint of adhesiveness and follow-up property. The surface to be laminated is usually a metal surface, but is not particularly restricted. The heating temperature for the photosensitive resin composition layer is preferably 70 to 130° C., and the contact bonding pressure is preferably about 0.1 to 1.0 MPa (about 1 to 10 kgf/cm²), although there is no restriction to these conditions. If the photosensitive resin composition layer is heated at 70 to 130° C. as described above, it is not necessary to preheat the circuit-forming board beforehand, but the circuit-forming board may be preheated for further improvement of laminating property.

The laminated photosensitive resin composition layer is irradiated with active light rays in an image pattern, through a negative or positive mask pattern referred to as artwork. When the polymer film on the photosensitive resin composition layer is transparent, direct irradiation with active light rays is possible, but it may need to be removed if it is opaque. A known light source such as, for example, a carbon arc lamp, a mercury vapor arc lamp, an ultra-high-pressure mercury lamp, a high-pressure mercury lamp or a xenon lamp, which efficiently emits ultraviolet rays, could be used as the light source for the active light rays. A lamp that efficiently emits visible light rays, such as a photoflood lamp or sun lamp may be also used.

In the exposure step for the photosensitive resin composition layer, it is preferred to employ a method for irradiating with active light rays in an image pattern by a laser direct drawing method such as DLP (Digital Light Processing) exposure method. A known light source may be used, such as a YAG laser, semiconductor laser or gallium nitride-based blue-violet laser, as the light source for the active light rays.

Next, after exposure, when the support remains on the photosensitive resin composition layer, the support is removed and then the unexposed portion is removed by development such as wet development or dry development, to form a resist pattern. In case of wet development, a developing solution suitable for photosensitive resin compositions such as an aqueous alkali solution, aqueous developing solution or organic solvent, may be used, and development may be accomplished by a known method such as spraying, reciprocal dipping, brushing or scrapping. The developing solution used is one which is safe and stable, and easily manageable, such as an aqueous alkali solution.

Examples of the base of the aqueous alkali solution include alkali metal hydroxides such as lithium, sodium or potassium hydroxide, alkali metal carbonates such as lithium, sodium or potassium carbonate or bicarbonate, ammonium carbonate or bicarbonate, alkali metal phosphates such as potassium phosphate or sodium phosphate, and alkali metal pyrophosphates such as sodium pyrophosphate or potassium pyrophosphate.

The aqueous alkali solution used for development is preferably a 0.1 to 5 wt % sodium carbonate dilute solution, a 0.1 to 5 wt % potassium carbonate dilute solution, a 0.1 to 5 wt % sodium hydroxide dilute solution, a 0.1 to 5 wt % sodium tetraborate dilute solution or the like. The pH of the aqueous alkali solution used for development is preferably in the range of 9 to 11, and the temperature is adjusted depending on the developing property of the photosensitive resin composition layer. Surfactants, antifoaming agents and small amounts of organic solvent to accelerate development may be added into the aqueous alkali solution.

An aqueous developing solution used is composed of water or an aqueous alkali solution and one or more different organic solvents. Examples of bases of aqueous alkali solutions other than those described above include borax, sodium metasilicate, tetramethylammonium hydroxide, ethanolamine, ethylenediamine, diethylenetriamine, 2-amino-2-hydroxymethyl-1,3-propanediol, 1,3-diaminopropanol-2, morpholine or the like. The pH of the developing solution is preferably as low as possible in a range allowing sufficient development of the resist, and preferably pH 8 to 12 and more preferably pH 9 to 10.

Examples of the organic solvent include triacetone alcohol, acetone, ethyl acetate, alkoxyethanols with C1-4 alkoxy groups, ethyl alcohol, isopropyl alcohol, butyl alcohol, diethyleneglycol monomethyl ether, diethyleneglycol monoethyl ether, diethyleneglycol monobutyl ether and the like. These may be used alone or in combinations of two or more. Normally, the concentration of the organic solvent is preferably 2 to 90 wt % and the temperature may be adjusted depending on the developing property. Small amounts of surfactants, antifoaming agents and the like may be added into the aqueous developing solution. Examples of organic solvent-based developing solutions to be used alone include 1,1,1-trichloroethane, N-methylpyrrolidone, N,N-dimethylformamide, cyclohexanone, methyl isobutyl ketone and γ-butyrolactone. Water is preferably added to these organic solvents in a range of 1 to 20 wt % for preventing ignition.

In a resist pattern formation method of the present invention, two or more developing methods described above may be carried out together as necessary. The developing system may be a dip system, paddle system, spray system, brushing, slapping or the like, and a high-pressure spray system is most suitable for improved resolution. Treatment following the development may comprise heating at 60 to 250° C. or exposure at an exposure dose of about 0.2 to 10 mJ/cm², if necessary, to further cure the resist pattern.

[Method of Producing a Printed Wiring Board]

When a printed wiring board is produced using a photosensitive element of the present invention, the surface of the circuit-forming board is treated by a known method such as etching or plating, using the developed resist pattern as a mask.

Etching of the metal surface may be accomplished using a cupric chloride solution, a ferric chloride solution, an alkali etching solution or a hydrogen peroxide-based etching solution, but in terms of good etch factor, a ferric chloride solution is preferred. The plating process may be, for example, copper plating such as copper sulfate plating or copper pyrophosphate plating, solder plating such as high throwing solder plating, nickel plating such as Watts bath (nickel sulfate-nickel chloride) plating or nickel sulfaminate plating, or gold plating such as hard gold plating or soft gold plating. These may use known methods as appropriate.

Then, the resist pattern may be released, for example, with an aqueous solution of stronger alkalinity than the aqueous alkali solution used for development. The strongly alkaline aqueous solution used here may be, for example, a 1 to 10 wt % sodium hydroxide aqueous solution or 1 to 10 wt % potassium hydroxide aqueous solution. The releasing system may be, for example, a dipping system, spraying system or the like, which may be used either alone or in combinations.

The method of producing a printed wiring board of the present invention as described above may be applied to manufacture of not only single-layer printed wiring boards but also multilayer printed wiring boards, and it may also be applied to manufacture of printed wiring boards with small through-holes. A printed wiring board may be produced with very high production efficiency, especially for a laser direct drawing method, by using the photosensitive resin composition and photosensitive element of the present invention, undergoing the series of steps described above to form a resist pattern, and etching or plating the circuit-forming board over which the resist pattern has been formed.

The preferred embodiments of the present invention has been described above, but the present invention is no way limited thereto.

### EXAMPLES

The present invention will be explained in further detail by the following examples below.

### Examples 1 to 5 and Comparative Examples 1 to 2

First, binder polymers were synthesized according to Synthesis Example 1.

### Synthesis Example 1

400 g of a mixture of methylcellosolve and toluene in a weight ratio of 6:4 was added to a flask equipped with a stirrer, reflux condenser, thermometer, dropping funnel and nitrogen gas inlet tube, and the obtained mixture was stirred while blowing in nitrogen gas and heated to 80° C. A mixed solution of 100 g of methacrylic acid, 250 g of methyl methacrylate, 100 g of ethyl acrylate, 50 g of styrene and 0.8 g of azobisisobutyronitrile (hereinbelow referred to as “solution a”) was prepared as a copolymerizing monomer, and the solution a was added dropwise over a period of 4 hours to the mixture of methylcellosolve and toluene in a weight ratio of 6/4 and which was heated to 80° C., after which the obtained mixture was kept at 80° C. for 2 hours while stirring. Further, a solution of 1.2 g of azobisisobutyronitrile dissolved in 100 g of a mixture of methylcellosolve and toluene in a weight ratio of 6/4 was added to the flask dropwise over a period of 10 minutes. After keeping the dropped solution at 80° C. for 3 hours while stirring, it was heated to 90° C. over a period of 30 minutes. After keeping it at 90° C. for 2 hours, it was cooled to obtain a binder polymer solution as component (A) (hereinbelow referred to as “A-1”). Acetone was added to this binder polymer solution to adjust to a non-volatilizing component content (solid content) of 50 wt %. The weight-average molecular weight of the binder polymer was 80,000. The weight-average molecular weight was measured by gel permeation chromatography, and calculation was performed using a standard polystyrene calibration curve. The GPC conditions were shown below.

(GPC Conditions)
Pump: Hitachi L-6000 (product name of Hitachi, Ltd.)
Column: Gelpack GL-R420 +Gelpack GL-R430 +Gelpack GL-R440 (total: 3) (all product names of Hitachi Chemical Co., Ltd.)
Eluent: tetrahydrofuran
Measuring temperature: 25° C.
Flow rate: 2.05 mL/min
Detector: Hitachi L-3300 RI (product name of Hitachi, Ltd.).

(Preparation of Photosensitive Resin Composition Solution)

The solutions of the photosensitive resin composition of Examples 1 to 5 and Comparative Examples 1 to 2 were prepared by combining the components listed in Table 1 in combination ratios (parts by weight) shown in Table 1. The combination ratios of component (A) shown in Table 1 represent weights of non-volatilizing components (solid content).

TABLE 1

| | | | | | | | Comparative | |
|---|---|---|---|---|---|---|---|---|
| | | Examples | | | | | Examples | |
| | | 1 | 2 | 3 | 4 | 5 | 1 | 2 |
| Compo- | A-1 | 60 | 60 | 60 | 60 | 60 | 60 | 60 |
| nent (A) | | | | | | | | |
| Compo- | BPE-500 | 20 | 20 | 20 | 20 | 20 | 20 | 20 |
| nent (B) | FA- | 10 | 10 | 10 | 10 | 10 | 10 | 10 |
| | MECH | | | | | | | |
| | UA-11 | 10 | 10 | 10 | 10 | — | 10 | 10 |
| | TMPT21 | — | — | — | — | 10 | — | — |
| Compo- | 9-X | 0.5 | — | — | — | 0.5 | — | — |
| nent (C) | 9-Y | — | 0.5 | — | 1.3 | — | — | — |
| | 9-Z | — | — | 0.15 | — | — | — | — |
| | N-1717 | 0.8 | 0.8 | 1 | — | 0.8 | 1.3 | — |
| | 9-PA | — | — | 0.15 | — | — | — | 1.3 |
| Compo- | BMPS | 1 | 1 | 1 | 1 | 1 | 1 | 1 |
| nent (D) | | | | | | | | |
| Additives | Malachite | 0.05 | 0.05 | 0.05 | 0.05 | 0.05 | 0.05 | 0.05 |
| | Green | | | | | | | |
| | Leuco | 0.5 | 0.5 | 0.5 | 0.5 | 0.5 | 0.5 | 0.5 |
| | Crystal | | | | | | | |
| | Violet | | | | | | | |
| Solvents | acetone | 5 | 5 | 5 | 5 | 5 | 5 | 5 |
| | toluene | 5 | 5 | 5 | 5 | 5 | 5 | 5 |
| | methanol | 5 | 5 | 5 | 5 | 5 | 5 | 5 |

The details of each component listed in the above table are as follows.

### Component (A): Binder Polymer

A-1: a copolymer of methacrylic acid/methyl methacrylate/ethyl acrylate/styrene (20/50/20/10 (weight ratio), weight-average molecular weight 80,000, 50 wt % methyl cellosolve/toluene=6/4 (weight ratio) solution)

### Component (B): Photopolymerizable Compound Having at Least One Ethylenically Unsaturated Bond

BPE-500 (product name of Shin-Nakamura Chemical Co., Ltd.): 2,2-bis(4-(methacryloxypentaethoxy)phenyl)propane
UA-11 (product name of Shin-Nakamura Chemical Co., Ltd.): EO-modified urethane dimethacrylate represented by the following formula (VI)

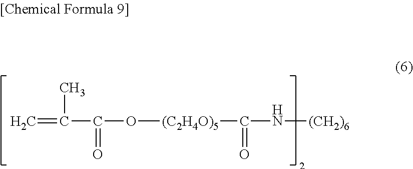

FA-MECH (product name of Hitachi Chemical Co., Ltd.): γ-chloro-β-hydroxypropyl-β′-methacryloyloxyethyl-o-phthalate
TMPT21 (product name of Hitachi Chemical Co., Ltd.): EO-modified trimethylolpropane trimethacrylate (average total number of EO chains=21)

### Component (C): Photopolymerization Initiator

9-X (product name of Changzhou Strong Electric New Material Co., Ltd.): 9-(p-methylphenyl)acridine
9-Y (product name of Changzhou Strong Electric New Material Co., Ltd.): 9-(m-methylphenyl)acridine
9-Z (product name of Changzhou Strong Electric New Material Co., Ltd.): 9-(p-chlorophenyl)acridine
N-1717 (product name of ADEKA Co., Ltd.): 1,7-bis(9,9-acridinyl)heptane
9-PA (product name of Nippon Steel Chemical Co., Ltd.): 9-phenylacridine

### Component (D)

BMPS (product name of Sumitomo Seika Chemicals Co., Ltd.): tribromomethylphenyl sulfone

(Photosensitive Element)

Then, the obtained solution of the photosensitive resin composition was evenly coated onto a 16 μm thick polyethylene terephthalate film (product name “G2-16” by Teijin, Ltd.) and dried for 10 minutes with a hot air convection drier at 100° C., and then protected with a polyethylene protective film (product name “NF-13” by Tamapoly Co., Ltd.) to obtain a photosensitive resin composition laminate (a photosensitive element). The post-drying film thickness of the photosensitive resin composition layer was 30 μm.

(Laminated Board)

Then, the copper surface of a copper-clad laminate (product name “MCL-E-67” by Hitachi Chemical Co., Ltd.) comprising a glass epoxy material with a copper foil (35 μm thickness) laminated on both sides, was polished using a polishing machine with a #600-equivalent brush (by Sankei Co., Ltd.), and after washing with water, it was dried with an air stream. The obtained copper-clad laminate was heated to 80° C., and the photosensitive resin composition layer was laminated on its copper surface using a heat roll at 110° C., at a speed of 1.5 m/min, while releasing the protective film, to obtain a test board.

(Evaluation of Photosensitivity)

A Hitachi 41-step tablet was placed on the test board, and exposed at 20 mJ/cm² using an exposure device employing a semiconductor laser as the light source (product name “DE-1AH” by Hitachi Via Mechanics Co., Ltd.). After exposure, the polyethylene terephthalate film was released, and sprayed with 1.0 wt % aqueous sodium carbonate at 30° C. for 40 seconds to remove the unexposed portion, and then the number of steps of the step tablet was measured for the photocured film formed on the copper-clad laminate, to evaluate the photosensitivity of the photosensitive resin composition. The photosensitivity is represented by the number of steps of the step tablet, and a higher step of the step tablet represents higher photosensitivity.

(Evaluation of Resolution and Adhesiveness)

The laminated test board was exposed with an energy dose for 14.0 steps remaining after development of Hitachi 41-step tablet, with photo-tool data having a wiring pattern with a line width/space width of 5/400 to 47/400 (units: μm) as the pattern for evaluation of adhesiveness. After developing treatment under the same conditions as for evaluation of the photosensitivity, the resist pattern was observed using an optical microscope, and the adhesiveness (μm) was evaluated based on the smallest value of the line width which remained without peeling and twisting. A smaller numerical value indicates better adhesiveness.

The laminated test board was exposed with an energy dose for 14.0 steps remaining after development of Hitachi 41-step tablet, with photo-tool data having a wiring pattern with a line width/space width ratio of 400/5 to 500/47 (units: μm) as the pattern for evaluation of resolution. After developing treatment under the same conditions as for evaluation of the photosensitivity, the resist pattern was observed using an optical microscope, and the resolution (μm) was evaluated based on the smallest value of the space width with which the unexposed portion was completely removed. A smaller numerical value indicates better resolution.

(Evaluation of Resist Shape)

The portions with the line width/space width of 45/400 (units: μm) in the resist patterns evaluated for the adhesiveness were observed using a Model S-2100A scanning electron microscope (by Hitachi, Ltd.) to evaluate the resist shape (presence or absence of mouse bites) according to the following criteria.
“absence”: Mouse bites were not observed on the resist skirt.
“presence”: Mouse bites were observed on the resist skirt.

The results of these evaluation measurements are shown in Table 2.

TABLE 2

| | | | | | | Comparative | Comparative |
|---|---|---|---|---|---|---|---|
| | Example 1 | Example 2 | Example 3 | Example 4 | Example 5 | Example 1 | Example 2 |
| Photosensitivity | 14.5 | 14.6 | 14.5 | 15.6 | 15.7 | 11 | 13.5 |
| (steps) | | | | | | | |
| Adhesiveness | 30 | 27 | 30 | 30 | 30 | 27 | 30 |
| (μm) | | | | | | | |
| Resolution | 35 | 35 | 35 | 35 | 32 | 35 | 35 |
| (μm) | | | | | | | |
| Mouse Bites | Absence | Absence | Absence | Absence | Absence | Presence | Absence |

As clearly seen in Table 2, Examples 1 to 5 that employed the compound represented by general formula (1) as a photopolymerization initiator had high photosensitivities, and good adhesivenesses, resolutions and resist shapes. Especially, Examples 4 and 5 had remarkable high photosensitivities. In contrast, Comparative Examples 1 to 2 that did not employ the compound represented by general formula (1) had lower sensitivities, and Comparative Example 1 had an inferior resist shape due to the occurrence of mouse bites.

### INDUSTRIAL APPLICABILITY

The present invention can provide a photosensitive resin composition that is excellent in photosensitivity, resolution and adhesiveness and that is able to form a resist pattern with good resist shape, as well as a photosensitive element, a method of a forming resist pattern and a method of producing a printed wiring board each utilizing same.

### REFERENCE SIGNS LIST

1: photosensitive element, 10: support, 14: photosensitive resin composition layer.

1. A photosensitive resin composition comprising (A) a binder polymer, (B) a photopolymerizable compound having an ethylenically unsaturated bond and (C) a photopolymerization initiator,
wherein the (C) photopolymerization initiator comprises a compound represented by the following general formula (1): 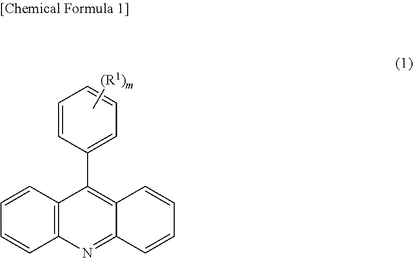
[in formula (1), R¹ represents a halogen atom, an amino group, a carboxyl group, a C1-6 alkyl group, a C1-6 alkoxy group or a C1-6 alkylamino group, m represents an integer of 1 to 5, and when m is 2 or greater, the multiple R¹ groups may be the same or different.].

2. The photosensitive resin composition according to claim 1, wherein the (C) photopolymerization initiator further comprises a compound represented by the following general formula (2): 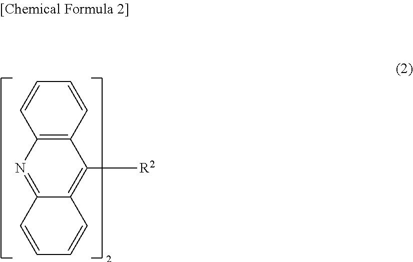
[in formula (2), R² represents a C2-20 alkylene, a C2-20 oxadialkylene or a C2-20 thiodialkylene group.].

3. The photosensitive resin composition according to claim 1, further comprising (D) a compound represented by the following general formula (3): 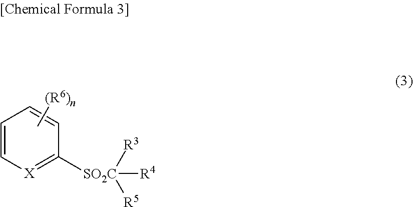
[in formula (3), X represents a carbon atom or a nitrogen atom, R³, R⁴ and R⁵ each independently represent a halogen atom or a C1-5 alkyl group and at least one of R³, R⁴ and R⁵ is a halogen atom, R⁶ represents a C1-5 alkyl group or a C 1-5 alkoxy group, n represents an integer of 0 to 4, and when n is 2 or greater, the multiple R⁶ groups may be the same or different.].

4. The photosensitive resin composition according to claim 1, wherein the (A) binder polymer has a structural unit based on (meth)acrylic acid.

5. The photosensitive resin composition according to claim 1, wherein the (A) binder polymer has a structural unit based on styrene or a styrene derivative.

6. The photosensitive resin composition according to claim 1, wherein the (B) photopolymerizable compound having an ethylenically unsaturated bond comprises a bisphenol A-based (meth)acrylate compound.

7. The photosensitive resin composition according to claim 1, wherein the (B) photopolymerizable compound having an ethylenically unsaturated bond comprises a compound represented by the following general formula (4): 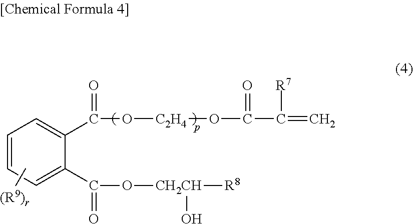
[in formula (4), R⁷ represents a hydrogen atom or a methyl group, R⁸ represents a hydrogen atom, a methyl group or a halogenated methyl group, R⁹ represents a C1-5 alkyl group, a halogen atom or a hydroxyl group, p represents an integer of 1 to 4, r represents an integer of 0 to 4, and when r is 2 or greater, the multiple R⁹ groups may be the same or different.].

8. A photosensitive element comprising a support and a photosensitive resin composition layer comprising the photosensitive resin composition according to claim 1 formed on the support.

9. A method of forming a resist pattern, comprising:
a lamination step of laminating a photosensitive resin composition layer comprising the photosensitive resin composition according to claim 1 on a circuit-forming board;
an exposure step of irradiating a predetermined portion of the photosensitive resin composition layer with active light rays to photocure the exposed portion; and
a developing step of removing a portion other than the exposed portion of the photosensitive resin composition layer to form a resist pattern.

10. A method of forming a resist pattern, comprising:
a lamination step of laminating the photosensitive resin composition layer of the photosensitive element according to claim 8 on a circuit-forming board;
an exposure step of irradiating a predetermined portion the photosensitive resin composition layer with active light rays to photocure the exposed portion; and
a developing step of removing a portion other than the exposed portion of the photosensitive resin composition layer to form a resist pattern.

11. The method of forming a resist pattern according to claim 9, wherein the exposure step is a step in which the photosensitive resin composition layer is subjected to direct drawing exposure with a laser light to photocure the exposed portion.

12. A method of producing a printed wiring board comprising a step of etching or plating a circuit-forming board having a resist pattern formed by the method of forming a resist pattern according to claim 9.
